(19) United States
(12) Patent Application Publication
(10) Pub. No.: US 2012/0152737 A1
(43) Pub. Date: Jun. 21, 2012

(54) LOADING DEVICE AND SPUTTERING DEVICE USING SAME

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 13/048,881

(22) Filed: Mar. 16, 2011

(30) Foreign Application Priority Data
Dec. 21, 2010 (TW) 99145091

(51) Int. Cl. C23C 14/34

(52) U.S. Cl. 204/298.12; 204/298.28

(57) ABSTRACT

A sputtering device includes a hollow main body, a loading device, and a driving device received in the main body. The main body includes a top plate and a bottom plate opposite to the top plate. The loading device includes a supporting base rotatably positioned on the bottom plate, a ring-shaped frame positioned on the top plate, and a number of rods. The ring-shaped frame is coaxial with the supporting base and includes a number of assembly plates connecting to each other in sequence. The rods are positioned on the supporting base along the circumference thereof, and substantially perpendicularly connect between the ring-shaped frame and the supporting base along the axis of the supporting base. The driving device connects to the supporting base and the rods, and drives the supporting base and driving the rods to rotate.

### BACKGROUND

1. Technical Field

The present disclosure relates to sputtering devices and, particularly, relates to a loading device and a sputtering device using same.

2. Description of Related Art

Sputtering devices often include a ring-shaped frame for fixing a number of rods, each of which is used for loading a number of workpieces (e.g., telephone shells). However, to fit in sputtering devices of different sizes, more than one ring-shaped frame having different diameters needs to be manufactured, which will increase the cost.

Therefore, it is desirable to provide a loading device and a sputtering device using same that can overcome the described limitations.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure.

FIG. 1 is a schematic view of a sputtering device, according to an exemplary embodiment.

FIG. 2 is a schematic view of a loading device of the sputtering device of FIG. 1.

FIG. 3 is a schematic view of a portion of a ring-shaped frame of the sputtering device of FIG. 1.

FIG. 4 is a schematic, top view of the loading device and a driving device of the sputtering device of FIG. 1.

### DETAILED DESCRIPTION

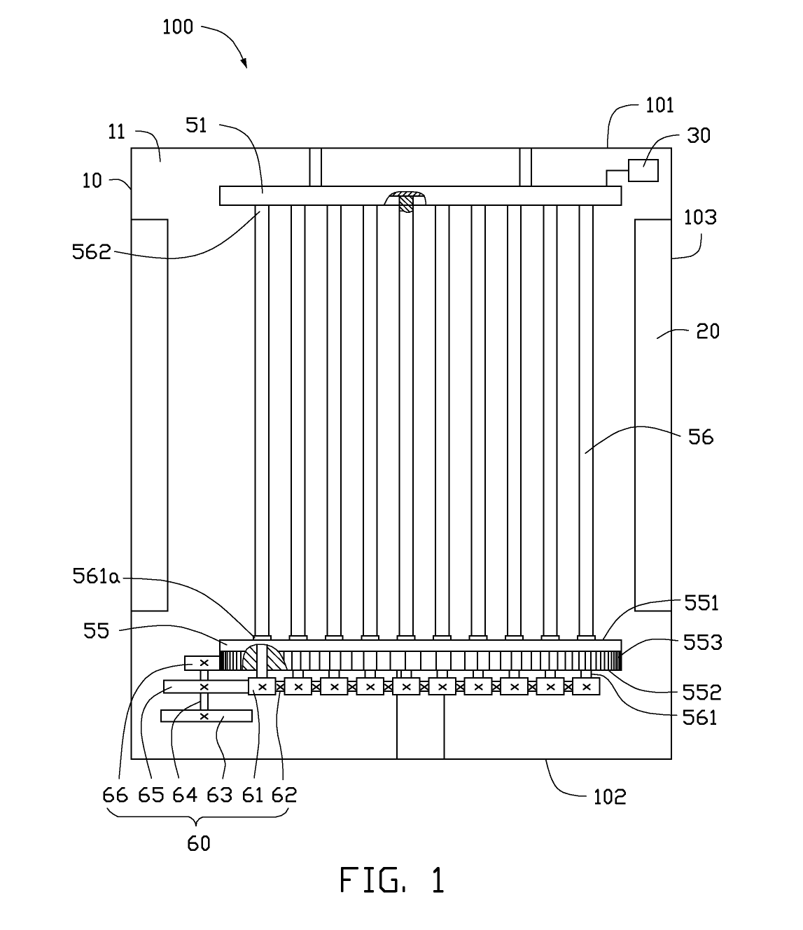

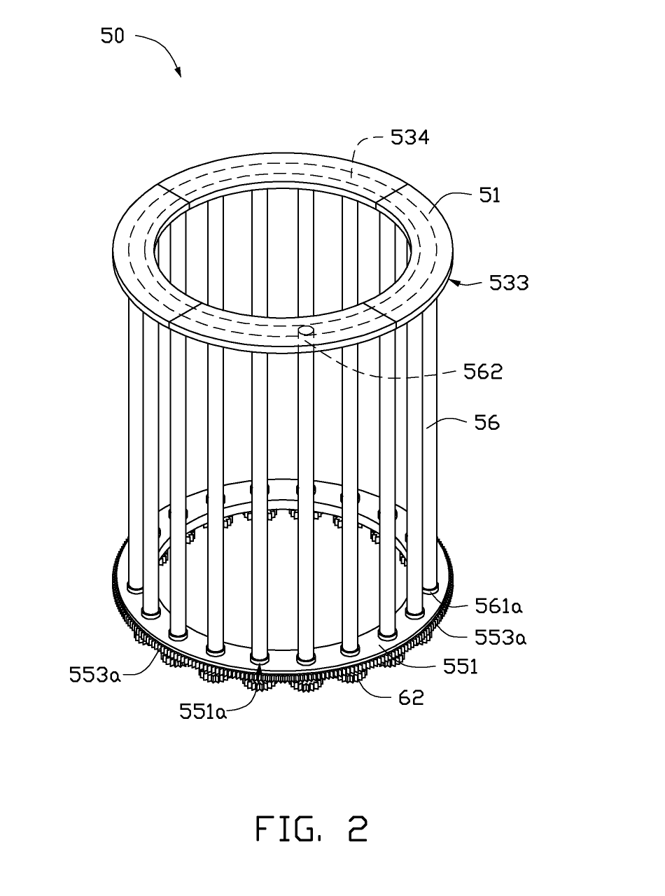

Referring to FIG. 1 and FIG. 2, a sputtering device 100, according to an exemplary embodiment, includes a main body 10, two targets 20, a biased electrode 30, a loading device 50, and a driving device 60.

The main body 10 is substantially a hollow cylinder and includes a top plate 101, a bottom plate 102 opposite to the top plate 101, and a tubular sidewall 103 connecting the top plate 101 and the bottom plate 102. The top plate 101, the bottom plate 102, and the sidewall 103 cooperatively define a cylindrical chamber 11.

The two targets 20 are used for providing ions having positive charge during the sputtering process. In this embodiment, the two targets 20 are titanium (Ti).

The biased electrode 30 is used for providing a negative voltage to the loading device 50.

The loading device 50 includes a ring-shaped supporting base 55, a ring-shaped frame 51, and a number of rods 56.

The supporting base 55 includes an annular loading surface 551, an annular bottom surface 552 opposite to the loading surface 551, and an outer circumference 553 which perpendicularly connects the loading surface 551 and the bottom surface 552. The supporting base 55 defines a number of through holes 551a in the loading surface 551. The through holes 551a are arranged along the circumference of the loading surface 551. The outer circumferential surface 553 is toothed and a number of teeth protruded therefrom.

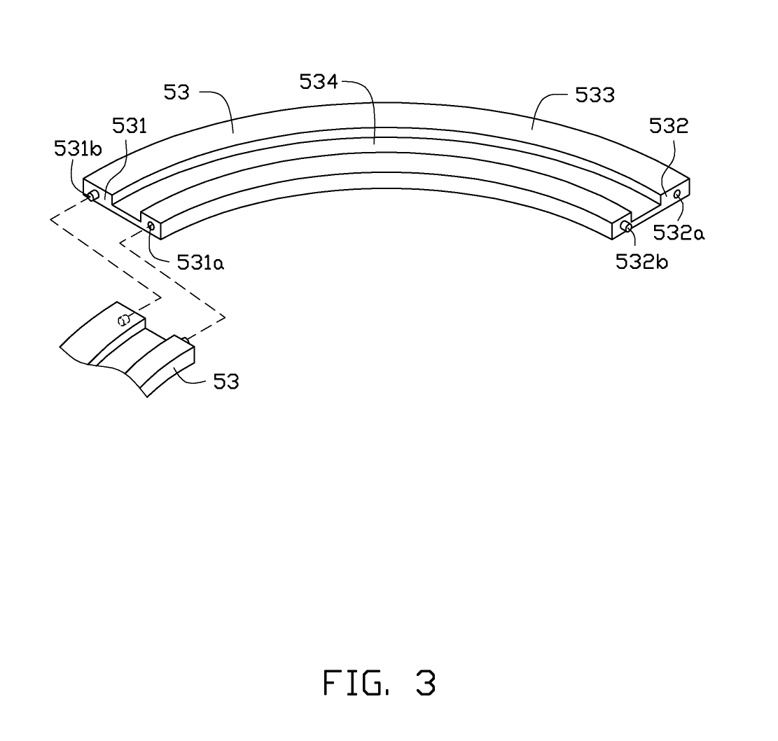

Also referring to FIG. 3, the ring-shaped frame 51 includes a number of (e.g., more than four) bent assembly plates 53 which are made of flexible, light, and conductive material. Before being bent, each assembly plate 53 is a rectangular sheet having a first end surface 531, and a second end surface 532 opposite to the first end surface 531, and a connecting surface 533 perpendicularly connecting the first and second end surfaces 531, 532. Each connecting surface 533 defines a sliding slot 534 along a direction substantially perpendicular to the first and second end surfaces 531, 532. The first end surface 531 defines a first hole 531a and a first pole 531b uprightly protruding from the first end surface 531. The second end surface 532 defines a second hole 532a corresponding to the first pole 531b and a second pole 532b protruding from the second end surface 532 and corresponding to the first hole 531a. More than two assembly plates 53 can be bent and combined to form the ring-shaped frame 51. In assembly, the first pole 531b, the first hole 531a of one assembly plate 53 are respectively fit in the second hole 532a, the second pole 532b of an adjacent assembly plate 53, and the assembly plate 53 is connected to the adjacent assembly plate 53. Thus, the diameter of the ring-shaped frame 51 can be adjusted by the number of the assembly plates employed.

The rods 56 are used for loading a number of workpieces (e.g., telephone shell) (not shown). Each rod 56 includes a first connecting end 561 and a second connecting end 562. A ring protrusion 561a protrudes from the first connecting end 561 of each rod 56 along the radial direction of the rod 56. The diameter of the ring protrusion 561a is larger than that of the through hole 551a. Each rod 56 passes through a corresponding through hole 551a until the ring protrusion 561a is stopped by the loading surface 551. The second connecting end 562 of each rod 56 is then received in the sliding slot 534, and contacts with the inner sidewall of the sliding slot 534.

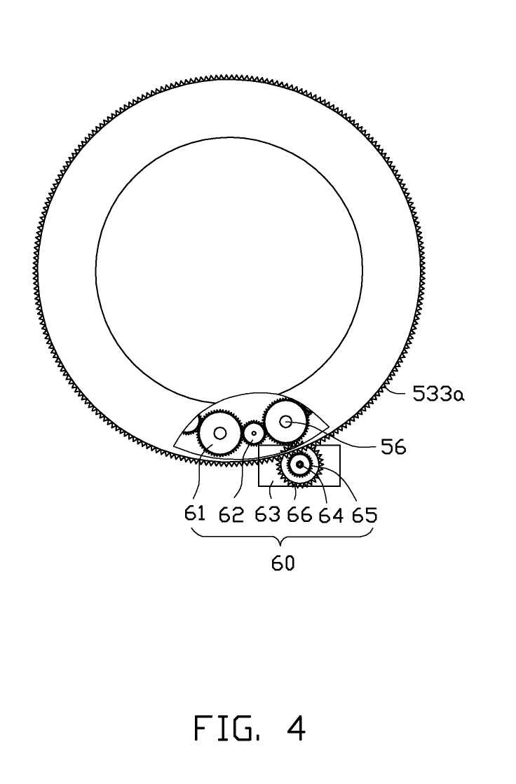

Referring to FIG. 4, the driving device 60 is used for driving the supporting base 55 and the rods 56 to rotate about the central axes thereof, and includes a number of follower gears 61, a number of transmission gears 62, a motor 63, a rotating shaft 64, a first driving gear 65, and a second driving gear 66. Each follower gear 61 is sleeved on a corresponding first connecting end 561 of the rod 56. Each transmission gear 62 is disposed between and meshes with two adjacent follower gears 61, and thus the two adjacent follower gears 61 can synchronously rotate, driven by the transmission gear 62. The motor 63 is used for driving the rotating shaft 64 to rotate about the central axis thereof. The first and second driving gears 65, 66 both sleeve on the rotating shaft 64 and are spaced a part. The first driving gear 65 is used for meshing with the gears 553a of the supporting base 55. The second driving gear 66 is used for meshing with one follower gear 61.

In assembly, the two targets 20 are attached to the inner surface of the sidewall 103 and are formed opposite to each other. The supporting base 55 is rotatably mounted on the bottom plate 102. According to the size of the supporting base 55, four sliding slots 534 cooperatively form a ring-shaped sliding slot coinciding with the through holes 551a of the supporting base 55. The ring-shaped frame 51 is mounted on the top plate 101 coaxial with the supporting base 55 and connecting to the biased electrode 30. The sliding slots 534 face the bottom plate 102. The second connecting ends 562 of the rod 56 are received in the sliding slots 534. The first connecting ends 561 of the rod 56 are inserted into the corresponding through holes 551a, and respectively extend downward from the bottom surface 552 of the supporting base 55. Each follower gear 61 sleeves a corresponding first connecting end 561. The first driving gear 65 meshes with the gear 553a of the supporting base 55. The second driving gear 66 meshes with one follower gear 61.

In use, the motor 63 drives the rotating shaft 64 to make the first and second driving gears 65, 66 rotate, and thus the supporting base 55 and the rods 56 respectively rotate about the central axes thereof. An electron beam (not shown) bombards the target 20 to sputter a lot of positive ions, the biased electrode 30 provides a negative voltage to the loading device 50 to speed up the positive ions to deposit on the workpieces positioned on the rod 56.

The connecting manner of the assembly plates 53 is not limited to this embodiment. The transmission gears 62 can be omitted, and the adjacent two follower gears 61 directly mesh with each other. The number of the targets 20 is not limited to this embodiment.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A loading device comprising:
a supporting base;
a ring-shaped frame coaxial with the supporting base and having a plurality of assembly plates connecting one by one; and
a plurality of rods substantially perpendicularly connecting between the supporting base and the ring-shaped frame along an axis of the supporting base.

2. The loading device of claim 1, wherein the assembly plates are made of flexible material, and comprises at least two assembly plates; the at least two assembly plates are bent and combined to form the ring-shaped frame.

3. The loading device of claim 2, wherein each assembly plate comprises a first end surface, a second end surface opposite to the first end surface, and a connecting surface connecting the first and second end surfaces, the connecting surface faces to the supporting base, the connecting surface defines a sliding slot along a lengthwise direction of the assembly plate from the first end surface to the second end surface, the sliding slots of all the assembly plates cooperatively form a ring-shaped sliding slot; the ring-shaped sliding slot receives one end of each rod.

4. The loading device of claim 3, wherein the supporting base has a ring-shaped loading surface and defines a number of through holes, the ring-shaped loading surface faces to the connecting surface, the through holes are arranged along the circumference direction of the loading surface and cooperatively define a ring coinciding with the ring-shaped sliding slot, each through hole receives a corresponding rod.

5. The loading device of claim 4, wherein each rod comprises a first connecting end inserted into a corresponding through hole, and a second connecting end received in the sliding slot.

6. The loading device of claim 5, wherein each rod comprises a ring protrusion, the ring protrusion protrudes from the first connecting end of each rod along the radial direction of the rod, a diameter of the ring protrusion is greater than that of each through hole, each rod passes through a corresponding through hole until the ring protrusion is stopped by the loading surface.

7. A sputtering device comprising:
a hollow main body comprising:
a top plate;
a bottom plate opposite to the top plate;
a loading device received in the main body and comprising:
a supporting base rotatably positioned on the bottom plate;
a ring-shaped frame positioned on the top plate and coaxial with the supporting base, the ring-shaped frame comprising a plurality of assembly plate connecting one by one; and
a plurality of rods positioned on the supporting base along the circumference direction of the supporting base, and substantially perpendicularly connecting between the ring-shaped frame and the supporting base along a axis of the supporting base;
a driving device received in the main body and connecting to the supporting base and the rods, the driving device configured for driving the supporting base to rotate and driving the rods to rotate.

8. The sputtering device of claim 7, wherein the assembly plates are made of a conductive material.

9. The sputtering device of claim 7, wherein each assembly plate comprises a first end surface, a second end surface opposite to the first end surface, and a connecting surface connecting to the first and second end surface, the connecting surface faces to the supporting base and defines a sliding slot along a lengthwise direction of the assembly plate from the first end surface to the second end surface, the sliding slots of all the assembly plates cooperatively form a ring-shaped sliding slot, the ring-shaped sliding slot receives one end of each rod.

10. The sputtering device of claim 9, wherein the supporting base has a ring-shaped loading surface and defines a number of through holes, the ring-shaped loading surface faces to the connecting surface, the through holes are arranged along the circumference direction of the loading surface, and cooperatively define a ring coinciding with the ring-shaped sliding slot, each through hole receives a corresponding rod.

11. The sputtering device of claim 10, wherein each rod comprises a first connecting end inserting into a corresponding through hole, and a second connecting end received in the sliding slot.

12. The sputtering device of claim 11, wherein each rod comprises a ring protrusion, the ring protrusion protrudes from the first connecting end of each rod along the radial direction of the rod, a diameter of the ring protrusion is greater than that of each through hole, each rod passes through a corresponding through hole until the ring protrusion is stopped by the loading surface.

13. The sputtering device of claim 12, wherein the driving device comprises a motor, a rotating shaft, and a first driving gear, the supporting base further comprises a toothed outer circumstance surface substantially perpendicular to the loading surface, the first driving gear sleeves on the rotating shaft and meshes the toothed outer circumstance surface of the supporting base, the motor is configured for driving the rotating shaft to rotate about the central axis thereof.

14. The sputtering device of claim 13, wherein the driving device further comprises a plurality of follower gears and a second driving gear, two adjacent follower gears mesh with each other, each follower gear sleeves on a corresponding first connecting end, the second driving gear sleeves on the rotating shaft and meshes with one of the follower gears.

15. The sputtering device of claim 13, wherein the driving device further comprises a plurality of follower gears, a plurality of transmission gears, and a second driving gear, each transmission gear is mounted between and meshes with two adjacent follower gears, each follower gear sleeves on a corresponding first connecting end, the second driving gear sleeves on the rotating shaft and meshes with one of the follower gears.

16. The sputtering device of claim 7, wherein the sputtering device further comprises a biased electrode configured for providing a negative voltage to the assembly plates.

17. The sputtering device of claim 7, wherein the main body further comprises a tubular sidewall connecting the top plate and the bottom plate, the sputtering device further comprises at least one target attached on an inner surface of the sidewall.
